(19) United States
(12) Patent Application Publication
(10) Pub. No.: US 2025/0132210 A1
(43) Pub. Date: Apr. 24, 2025

(54) SEMICONDUCTOR STRUCTURE AND FABRICATION METHOD THEREOF

(71) Applicant: UNITED MICROELECTRONICS CORP., Hsin-Chu City (TW)

(72) Inventors: Yao-Hsien Chung, Tainan City (TW); Tai-Cheng Hou, Tainan City (TW); Chin-Chia Yang, Tainan City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/527,400

(22) Filed: Dec. 4, 2023

(30) Foreign Application Priority Data
Oct. 24, 2023 (CN) 202311384431.8

(51) Int. Cl. H01L 23/26; H01L 21/02; H01L 21/768; H01L 23/532

(52) U.S. Cl. CPC H01L 23/26; H01L 21/0214; H01L 21/02164; H01L 21/76829; H01L 23/53228

(57) ABSTRACT

A wafer structure includes a substrate having a pre-bonding structure thereon. The pre-bonding structure includes an outer dielectric layer covering a central region of the substrate and a ring-shaped absorbent layer within a ring-shaped peripheral region of the substrate. The ring-shaped absorbent layer is contiguous with the outer dielectric layer.

### BACKGROUND OF THE INVENTION

### 1. Field of the Invention

The present invention relates to the field of semiconductor technology, and in particular, to an improved semiconductor structure and a manufacturing method thereof.

### 2. Description of the Prior Art

Wafer bonding is a process for temporary or permanent joining of two or more wafers with or without an intermediate layer. The formation of edge bonding voids during direct wafer bonding is problematic. A gas pressure drop occurs at the wafer edge described by a Joule-Thomson expansion. This adiabatic process results in a gas temperature change which can lead to the condensation of small water droplets close to the wafer edge.

To avoid such bonding defects, typically, the gas atmosphere during the wafer bonding process is controlled. There is a need in this technical field to provide an improved semiconductor structure to avoid the formation of edge bonding voids during the wafer bonding process.

### SUMMARY OF THE INVENTION

It is one object of the present invention to provide an improved semiconductor structure and a manufacturing method thereof to solve the deficiencies or shortcomings of the prior art.

One aspect of the invention provides a wafer structure including a substrate; an interconnection structure disposed on the substrate; a cap layer disposed on the interconnection structure; a top dielectric layer disposed on the cap layer; a pre-bonding structure disposed on the top dielectric layer, wherein the pre-bonding structure comprises an inner layer on the top dielectric layer, an outer layer, and an intermediate absorbent layer being contiguous with the inner layer and disposed along a perimeter of the outer layer; and a plurality of copper pads disposed in the pre-bonding structure, the top dielectric layer and the cap layer.

According to some embodiments, the intermediate absorbent layer is exposed within a peripheral region at an edge portion of the wafer structure.

According to some embodiments, the peripheral region has a width of about 10 mm.

According to some embodiments, the outer layer does not cover the intermediate absorbent layer within the peripheral region.

According to some embodiments, the intermediate absorbent layer comprises porous dielectric material and has a thickness of about 100-200 angstroms.

According to some embodiments, the inner layer comprises nitrogen-doped silicon carbide and has a thickness of about 200-2000 angstroms.

According to some embodiments, the outer layer comprises silicon oxynitride and has a thickness of about 200-800 angstroms.

According to some embodiments, the cap layer comprises nitrogen-doped silicon carbide and has a thickness of about 500-700 angstroms.

According to some embodiments, the top dielectric layer comprises silicon oxide and has a thickness of about 9000-9500 angstroms.

According to some embodiments, the plurality of copper pads penetrates through the pre-bonding structure, the top dielectric layer, and the cap layer, and is electrically connected to the interconnection structure.

Another aspect of the invention provides a method for forming a wafer structure including the steps of: providing a substrate; forming an interconnection structure on the substrate; forming a cap layer on the interconnection structure; forming a top dielectric layer on the cap layer; forming a pre-bonding structure on the top dielectric layer, wherein the pre-bonding structure comprises an inner layer on the top dielectric layer, an outer layer, and an intermediate absorbent layer being contiguous with the inner layer and disposed along a perimeter of the outer layer; and forming a plurality of copper pads in the pre-bonding structure, the top dielectric layer and the cap layer.

According to some embodiments, the intermediate absorbent layer is exposed within a peripheral region at an edge portion of the wafer structure.

According to some embodiments, the peripheral region has a width of about 10 mm.

According to some embodiments, the outer layer does not cover the intermediate absorbent layer within the peripheral region.

According to some embodiments, the intermediate absorbent layer comprises porous dielectric material and has a thickness of about 100-200 angstroms.

According to some embodiments, the inner layer comprises nitrogen-doped silicon carbide and has a thickness of about 200-2000 angstroms.

According to some embodiments, the outer layer comprises silicon oxynitride and has a thickness of about 200-800 angstroms.

According to some embodiments, the cap layer comprises nitrogen-doped silicon carbide and has a thickness of about 500-700 angstroms.

According to some embodiments, the top dielectric layer comprises silicon oxide and has a thickness of about 9000-9500 angstroms.

According to some embodiments, the plurality of copper pads penetrates through the pre-bonding structure, the top dielectric layer, and the cap layer, and is electrically connected to the interconnection structure.

Still another aspect of the invention provides a wafer structure including a substrate having a pre-bonding structure thereon, wherein the pre-bonding structure comprises an outer dielectric layer covering a central region of the substrate and a ring-shaped absorbent layer covering a ring-shaped peripheral region of the substrate, wherein the ring-shaped absorbent layer is contiguous with the outer dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a wafer structure according to an embodiment of the present invention.

FIG. 2 is a schematic cross-sectional view taken along the line I-I′ in FIG. 1.

FIG. 3 to FIG. 5 illustrate a method of forming a wafer structure according to an embodiment of the invention.

FIG. 6 to FIG. 8 illustrate a method of forming a wafer structure according to another embodiment of the invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

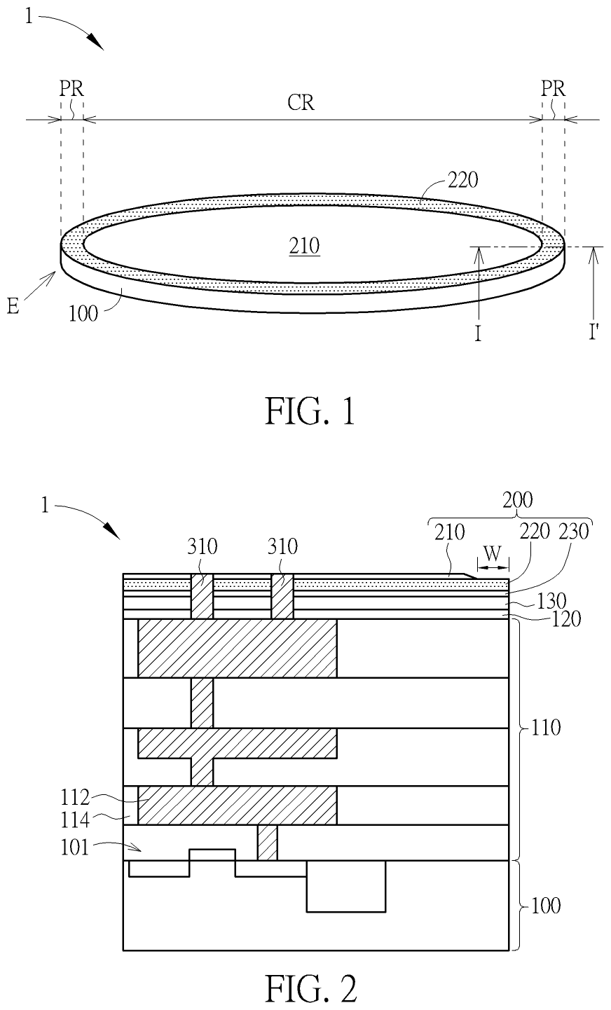

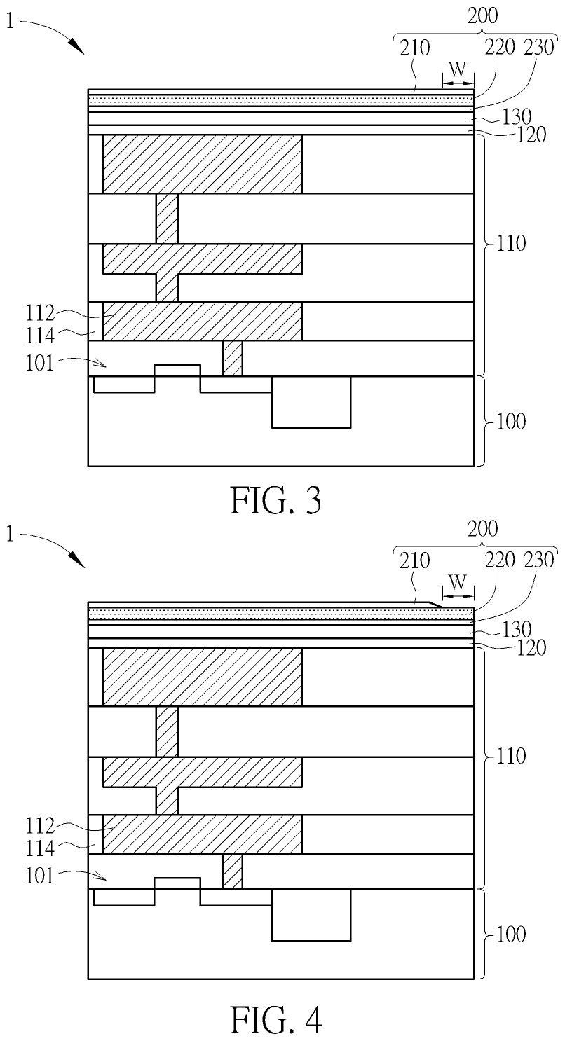

Please refer to FIG. 1 and FIG. 2. FIG. 1 illustrates a wafer structure according to an embodiment of the present invention. FIG. 2 is a schematic cross-sectional view taken along the line I-I′ in FIG. 1. As shown in FIG. 1, the wafer structure 1 includes a disc-shaped substrate 100, for example, a silicon substrate or a silicon-on-insulator (SOI) substrate, with a pre-bonding structure 200 thereon. According to an embodiment of the present invention, the pre-bonding structure 200 includes an outer dielectric layer (or outer layer) 210 covering a central region CR of the substrate 100 and an annular-shaped, intermediate absorbent layer 220 covering an annular peripheral region PR of the substrate 100. According to an embodiment of the present invention, the annular-shaped, intermediate absorbent layer 220 is contiguous with the outer dielectric layer 210. According to an embodiment of the present invention, the width w of the annular peripheral region PR is approximately 10 mm.

As shown in FIG. 2, a semiconductor device 101 may be formed on the substrate 100. For example, the semiconductor device 101 may comprise a transistor, but is not limited thereto. According to an embodiment of the present invention, an interconnection structure 110 is further formed on the substrate 100. According to embodiments of the present invention, for example, the interconnection structure 110 may include a plurality of layers of metal conductors 112 and a plurality of dielectric layers 114.

According to an embodiment of the present invention, a cap layer 120 is provided on the interconnection structure 110. According to some embodiments of the present invention, for example, the cap layer 120 may include nitrogen-doped silicon carbide, but is not limited thereto. According to some embodiments of the present invention, for example, the thickness of the cap layer 120 is about 500-700 angstroms. According to an embodiment of the present invention, a top dielectric layer 130 is provided on the cap layer 120. According to some embodiments of the present invention, for example, the top dielectric layer 130 may include silicon oxide. According to some embodiments of the present invention, for example, the thickness of the top dielectric layer 130 is about 9000-9500 angstroms.

As shown in FIG. 1 and FIG. 2, according to an embodiment of the present invention, a pre-bonding structure 200 is disposed on the top dielectric layer 130. According to an embodiment of the present invention, for example, the pre-bonding structure 200 includes an inner layer 230 disposed on the top dielectric layer 130, an outer layer 210, and an intermediate absorbent layer 220 that is contiguous with the inner layer 230 and is disposed along the perimeter of the outer layer 210. According to an embodiment of the present invention, the intermediate absorbent layer 220 is exposed in the peripheral region PR at the edge portion E of the wafer structure 1. According to an embodiment of the invention, the outer layer 210 does not cover the intermediate absorbent layer 220 in the peripheral region PR.

In FIG. 2, the intermediate absorbent layer 220 is sandwiched between the inner layer 230 and the outer layer 210, and only the intermediate absorbent layer 220 in the peripheral region PR is exposed. The outer layer 210 has a tapered cross-sectional profile near the peripheral region PR. According to another embodiment of the present invention, the intermediate absorbent layer 220 is only formed in the peripheral region PR, the outer layer 210 may directly contact the inner layer 230, and the intermediate absorbent layer 220 is not sandwiched between the inner layer 230 and the outer layer 210.

According to an embodiment of the present invention, the intermediate absorbent layer 220 includes a porous dielectric material and has a thickness of about 100-200 angstroms. According to an embodiment of the present invention, the intermediate absorbent layer 220 includes ultra-low dielectric constant (ultra-low k or ULK) material or porous material that can easily absorb water vapor or moisture. According to an embodiment of the present invention, the inner layer 230 includes nitrogen-doped silicon carbide and may have a thickness of approximately 200-2000 angstroms. According to an embodiment of the present invention, the outer layer 210 includes silicon oxynitride and may have a thickness of about 200-800 angstroms.

According to an embodiment of the present invention, the wafer structure 1 further includes a plurality of copper pads 310 disposed in the pre-bonding structure 200, the top dielectric layer 130 and the cap layer 120. According to an embodiment of the present invention, the plurality of copper pads 310 penetrates through the pre-bonding structure 200, the top dielectric layer 130 and the cap layer 120 and is electrically connected to the interconnection structure 110. During wafer bonding, these copper pads 310 will be bonded with the corresponding copper pads of another wafer, and the intermediate absorbent layer 220 can absorb or trap water molecules located at the edge E of the wafer, thereby effectively avoiding the formation of the edge bonding voids. Since the intermediate absorbent layer 220 is made of ULK material, the electrical properties and performance of the chip can be further improved.

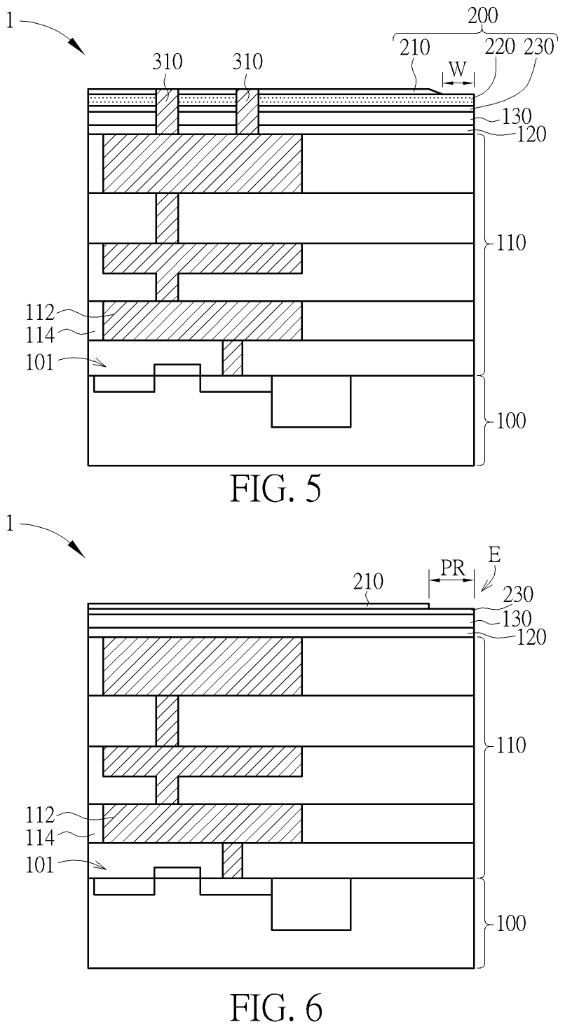

Please refer to FIG. 3 to FIG. 5, which illustrate a method of forming a wafer structure according to an embodiment of the invention. As shown in FIG. 3, a substrate 100 is first provided, for example, a silicon substrate or a silicon-on-insulator substrate. Next, a metallization process is performed to form the interconnection structure 110 on the substrate 100. According to embodiments of the present invention, for example, the interconnection structure 110 may include a plurality of layers of metal conductors 112 and a plurality of dielectric layers 114.

Subsequently, a cap layer 120 is formed on the interconnection structure 110 using a chemical vapor deposition (CVD) process. According to some embodiments of the present invention, for example, the cap layer 120 may include nitrogen-doped silicon carbide, but is not limited thereto. According to some embodiments of the present invention, for example, the thickness of the cap layer 120 is about 500-700 angstroms.

Subsequently, a chemical vapor deposition process is performed to form a top dielectric layer 130 on the cap layer 120. According to some embodiments of the present invention, for example, the top dielectric layer 130 may include silicon oxide. According to some embodiments of the present invention, for example, the thickness of the top dielectric layer 130 is about 9000-9500 angstroms.

Subsequently, a chemical vapor deposition process is used to form the pre-bonding structure 200 on the top dielectric layer 130. According to an embodiment of the present invention, the pre-bonding structure 200 includes an inner layer 230 located on the top dielectric layer 130, an outer layer 210, and an intermediate absorbent layer 220 that is contiguous with the inner layer 230 and is disposed along the perimeter of the outer layer 210. According to an embodiment of the present invention, the intermediate absorbent layer 220 is exposed in the peripheral region PR at the edge portion E of the wafer structure 1. According to an embodiment of the invention, the outer layer 210 does not cover the intermediate absorbent layer 220 in the peripheral region PR. According to an embodiment of the present invention, the width w of the peripheral region PR is approximately 10 mm.

According to an embodiment of the present invention, the intermediate absorbent layer 220 includes a porous dielectric material and may have a thickness of about 100-200 angstroms. According to embodiments of the present invention, the intermediate absorbent layer 220 includes ultra-low dielectric constant material or porous material that can easily absorb water vapor or moisture. According to an embodiment of the present invention, the inner layer 230 includes nitrogen-doped silicon carbide and may have a thickness of about 200-2000 angstroms. According to an embodiment of the present invention, the outer layer 210 includes silicon oxynitride and may have a thickness of about 200-800 Angstroms.

As shown in FIG. 4, a polishing process, such as a chemical mechanical polishing (CMP) process, is used to remove the outer layer 210 of the peripheral region PR, thereby exposing the intermediate absorbent layer 220 in the peripheral region PR. At this point, the outer layer 210 has a tapered cross-sectional profile near the peripheral region PR.

As shown in FIG. 5, a metallization process is then performed to form a plurality of copper pads 310 in the pre-bonding structure 200, the top dielectric layer 130 and the cap layer 120. According to an embodiment of the present invention, the plurality of copper pads 310 penetrates through the pre-bonding structure 200, the top dielectric layer 130 and the cap layer 120 and is electrically connected to the interconnection structure 110.

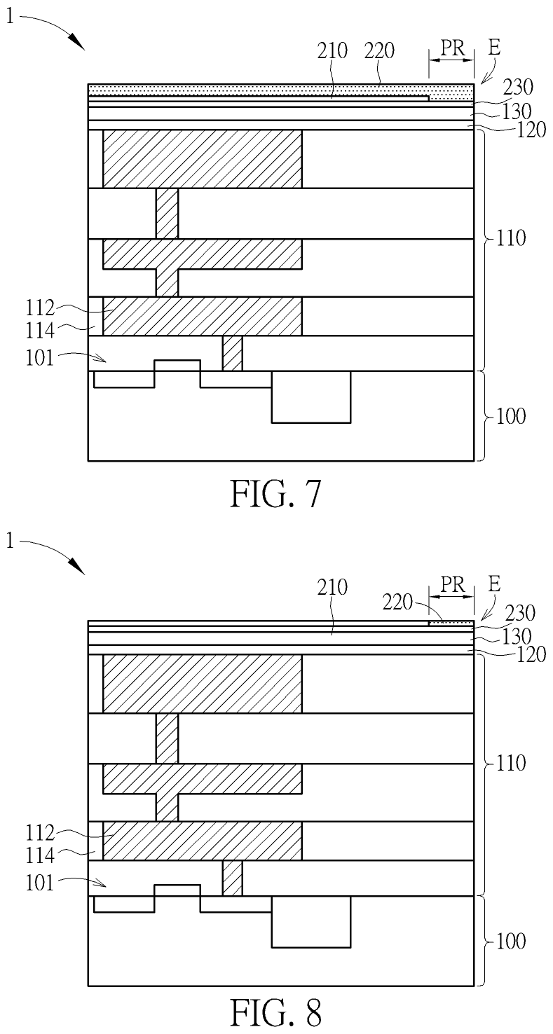

Please refer to FIG. 6 to FIG. 8, which illustrate a method of forming a wafer structure according to another embodiment of the invention. As shown in FIG. 6, a substrate 100 is first provided, for example, a silicon substrate or a silicon-on-insulator substrate. Next, a metallization process is performed to form the interconnection structure 110 on the substrate 100. According to some embodiments of the present invention, for example, the interconnection structure 110 may include a plurality of layers of metal conductors 112 and a plurality of dielectric layers 114.

Subsequently, a cap layer 120 is formed on the interconnection structure 110 using a chemical vapor deposition process. According to some embodiments of the present invention, for example, the cap layer 120 may include nitrogen-doped silicon carbide, but is not limited thereto. According to embodiments of the present invention, for example, the thickness of the cap layer 120 is about 500-700 angstroms.

Subsequently, a chemical vapor deposition process is performed to form a top dielectric layer 130 on the cap layer 120. According to some embodiments of the present invention, for example, the top dielectric layer 130 may include silicon oxide. According to some embodiments of the present invention, for example, the thickness of the top dielectric layer 130 is about 9000-9500 angstroms.

Next, an inner layer 230 and a patterned outer layer 210 are formed on the top dielectric layer 130 using a chemical vapor deposition process. The inner layer 230 in the peripheral region PR at the edge portion E of the wafer structure 1 is exposed. According to an embodiment of the present invention, the inner layer 230 may include nitrogen-doped silicon carbide and may have a thickness of approximately 200-2000 angstroms. According to an embodiment of the present invention, the outer layer 210 may include silicon oxynitride and may have a thickness of about 200-800 angstroms.

As shown in FIG. 7, a chemical vapor deposition process or a coating process is then performed to blanket deposit an intermediate absorbent layer 220 on the inner layer 230 of the peripheral region PR and the patterned outer layer 210. According to an embodiment of the present invention, the intermediate absorbent layer 220 may include a porous dielectric material and may have a thickness of about 100-200 angstroms. According to some embodiments of the present invention, the intermediate absorbent layer 220 may include ultra-low dielectric constant material or porous material that can easily absorb water vapor or moisture.

As shown in FIG. 8, a polishing process, such as a chemical mechanical polishing process, is then performed to remove the intermediate absorbent layer 220 located on the patterned outer layer 210, thereby forming intermediate absorbent layer 220 that is contiguous with the inner layer 230 and is disposed along the perimeter of the outer layer 210. According to an embodiment of the present invention, the intermediate absorbent layer 220 is exposed in the peripheral region PR at the edge portion E of the wafer structure 1. According to an embodiment of the invention, the outer layer 210 does not cover the intermediate absorbent layer 220 in the peripheral region PR.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer structure, comprising:
a substrate;
an interconnection structure disposed on the substrate;
a cap layer disposed on the interconnection structure;
a top dielectric layer disposed on the cap layer;
a pre-bonding structure disposed on the top dielectric layer, wherein the pre-bonding structure comprises an inner layer on the top dielectric layer, an outer layer, and an intermediate absorbent layer being contiguous with the inner layer and disposed along a perimeter of the outer layer; and
a plurality of copper pads disposed in the pre-bonding structure, the top dielectric layer and the cap layer.

2. The wafer structure according to claim 1, wherein the intermediate absorbent layer is exposed within a peripheral region at an edge portion of the wafer structure.

3. The wafer structure according to claim 2, wherein the peripheral region has a width of about 10 mm.

4. The wafer structure according to claim 2, wherein the outer layer does not cover the intermediate absorbent layer within the peripheral region.

5. The wafer structure according to claim 1, wherein the intermediate absorbent layer comprises porous dielectric material and has a thickness of about 100-200 angstroms.

6. The wafer structure according to claim 1, wherein the inner layer comprises nitrogen-doped silicon carbide and has a thickness of about 200-2000 angstroms.

7. The wafer structure according to claim 1, wherein the outer layer comprises silicon oxynitride and has a thickness of about 200-800 angstroms.

8. The wafer structure according to claim 1, wherein the cap layer comprises nitrogen-doped silicon carbide and has a thickness of about 500-700 angstroms.

9. The wafer structure according to claim 1, wherein the top dielectric layer comprises silicon oxide and has a thickness of about 9000-9500 angstroms.

10. The wafer structure according to claim 1, wherein the plurality of copper pads penetrates through the pre-bonding structure, the top dielectric layer, and the cap layer, and is electrically connected to the interconnection structure.

11. A method for forming a wafer structure, comprising:
providing a substrate;
forming an interconnection structure on the substrate;
forming a cap layer on the interconnection structure;
forming a top dielectric layer on the cap layer;
forming a pre-bonding structure on the top dielectric layer, wherein the pre-bonding structure comprises an inner layer on the top dielectric layer, an outer layer, and an intermediate absorbent layer being contiguous with the inner layer and disposed along a perimeter of the outer layer; and
forming a plurality of copper pads in the pre-bonding structure, the top dielectric layer and the cap layer.

12. The method according to claim 11, wherein the intermediate absorbent layer is exposed within a peripheral region at an edge portion of the wafer structure.

13. The method according to claim 12, wherein the peripheral region has a width of about 10 mm.

14. The method according to claim 12, wherein the outer layer does not cover the intermediate absorbent layer within the peripheral region.

15. The method according to claim 11, wherein the intermediate absorbent layer comprises porous dielectric material and has a thickness of about 100-200 angstroms.

16. The method according to claim 11, wherein the inner layer comprises nitrogen-doped silicon carbide and has a thickness of about 200-2000 angstroms.

17. The method according to claim 11, wherein the outer layer comprises silicon oxynitride and has a thickness of about 200-800 angstroms.

18. The method according to claim 11, wherein the cap layer comprises nitrogen-doped silicon carbide and has a thickness of about 500-700 angstroms.

19. The method according to claim 11, wherein the top dielectric layer comprises silicon oxide and has a thickness of about 9000-9500 angstroms.

20. The method according to claim 11, wherein the plurality of copper pads penetrates through the pre-bonding structure, the top dielectric layer, and the cap layer, and is electrically connected to the interconnection structure.

21. A wafer structure, comprising:
a substrate having a pre-bonding structure thereon, wherein the pre-bonding structure comprises an outer dielectric layer covering a central region of the substrate and a ring-shaped absorbent layer covering a ring-shaped peripheral region of the substrate, wherein the ring-shaped absorbent layer is contiguous with the outer dielectric layer.
